(19) United States
(12) Patent Application Publication
(10) Pub. No.: US 2007/0147635 A1
(43) Pub. Date: Jun. 28, 2007

(54) System and method for separation of a user's voice from ambient sound

(75) Inventors: Evert Dijkstra, Fontaines (CH); Olivier Hautier, Savagnier (CH); Nicolas Destrez, Fribourg (CH)

Correspondence Address: ROBERTS, MLOTKOWSKI & HOBBES, P. O. BOX 10064, MCLEAN, VA, 22102-8064, US

(73) Assignee: Phonak AG, Staefa (CH)

(21) Appl. No.: 11/316,384

(22) Filed: Dec. 23, 2005

(51) Int. Cl. H04B 15/00; G06F 15/00; H03F 1/26

(52) U.S. Cl. 381/94.1; 381/94.2; 702/190

(57) ABSTRACT

A system for separation of a user's voice from ambient sound, comprising a device to be worn at the user's ear or at least partly in the user's ear canal comprising a first microphone oriented outwardly towards the environment and a second microphone oriented inwardly towards the user's ear canal, and an audio signal processing unit for processing audio signals from the first and second microphone by a blind source separation algorithm adapted to separate the user's voice from ambient sound.

### BACKGROUND OF THE INVENTION

1. Field of the Invention

The present invention relates to a system and a method for separation of a user's voice from ambient sound by using at least one device to be worn at the user's ear or at least partly in the user's ear canal.

2. Description of Related Art

For communication purposes, in particular for wireless electronic communication between or from persons exposed to a noisy environment, such as workers in industrial plants, policemen, soldiers, firemen, etc., it is desirable to have a sound pick-up system which is capable at least to some extent to separate the user's voice from ambient noise, or generally ambient sound, in order to improve the intelligibility of the person's speech to the listener, who may be one of the other persons exposed to the noisy environment or who may be a remote person.

A common approach to achieve such separation of a person's voice is the use of a boom microphone, i.e. a microphone which is placed close to the mouth, carried by a headset, helmet or any other device worn by the person. Such microphone selectively emphasizes the near field around the mouth.

Other approaches are vibration pick-up devices which are in direct contact with the throat, picking up the vibrations of the vocal chord, or which are in direct contact with the meatus wall or the outer ear canal, picking up the vibrations of the head tissue (i.e. “bone conduction” microphones) or which are in direct contact with the cheek-bone.

Devices of these types are either fairly sensitive to acoustic noise masking the speech or certain speech sounds are poorly transmitted, especially the high frequency consonant sounds necessary for good intelligibility. Furthermore, for industrial applications boom microphones have the drawbacks that they limit the freedom of movement of the user and that, when combined with a hearing protection device, they will affect the stability and hence the attenuation of the hearing protection device. Bone-conduction microphones have the drawbacks that they have a very limited audio bandwidth which limits the intelligibility of the speech and that they often have to be pressed fairly hard which causes discomfort to the user.

U.S. Pat. No. 6,661,901 B1 relates to an active hearing protection system comprising an earplug with an outer microphone for picking up ambient sound and an inner microphone which is sealed with respect to ambient sound but is open towards the inner part of the user's ear canal. In an operation mode in which separation of the user's voice from ambient noise is desired only the inner microphone is activated while the outer microphone is not, with the signal from the inner microphone being processed by an electronics unit integrated within the earplug in order to make the user's voice highly natural and intelligible, either for the user himself or his external communication partners.

Another approach is based on a so-called “blind source separation” (BSS) algorithm in order to separate a person's voice from background noise by corresponding audio signal processing. In this respect, US 2003/0055535 A1 relates to the use of a BSS algorithm for separating the voice of an operator of a vehicle wheel alignment system with a voice audio interface from background noise by using a microphone array in order to avoid the necessity to use a headset. US 2005/0060142 A1 relates in a more general manner to the use of two spaced-apart microphones operated with a BSS algorithm for voice separation from background noise in audio applications.

It is an object of the invention to provide for a system and a method for separation of a person's voice from ambient sound wherein good intelligibility of speech is achieved while nevertheless discomfort to the person is to be avoided as far as possible.

### SUMMARY OF THE INVENTION

According to the invention this object is achieved by a system as defined in claims 1 and 25, and by corresponding methods as defined in claims 28 and 29, respectively.

The invention is beneficial in that, by using a first microphone and a second microphone, wherein according to the solution of claims 1 and 28 the first microphone is oriented outwardly towards the environment and the second microphone oriented inwardly towards the user's ear canal and according to the solution of claims 25 and 29 the first microphone is located at the right ear and the second microphone is located at the left ear, and by processing the audio signals from the first and second microphone by a blind source separation algorithm, good separation of the user's voice from ambient sound with resulting high intelligibility of the user's speech is achieved without the need for additional restrictions regarding the location of the microphones, so that in particular the need for a boom microphone or a bone-conduction microphone can be avoided. In particular, by orienting the first microphone towards the environment and orienting the second microphone towards the user's ear canal or by locating the first microphone at the right ear and the second microphone at the left ear these two microphones pick up sufficiently differently mixed signals of the ambient sound and the user's voice so that a BSS algorithm will work efficiently.

Generally, blind source separation (also referred to as “independent component analysis” (ICA)) is a technique for separating mixed source signals (components) which are presumably statistically independent from each other. In its simplified form, blind source separation applies an “un-mixing” matrix of weights to the mixed signals, for example, multiplying the matrix with the mixed signals, to produce separated signals. The weights are assigned initial values, and then adjusted to maximize joint entropy of the signals in order to minimize information redundancy. This weight-adjusting and entropy-increasing process is repeated until the information redundancy of the signals is reduced to a minimum. Because this technique does not require information on the source of each signal, it is referred to as “blind source separation”. An introduction to blind source separation is found, for example, in US 2005/0060142 A1.

In the most simple case, BSS is applied to two different mixtures of two (acoustic) sources, wherein the two different mixtures are obtained by using two spaced apart microphones. Mixing of the two sources can be represented by a matrix A, with the BSS algorithm corresponding mathematically to finding the inverse matrix of A without knowing anything about the matrix nor about the sources, except that they are statistically independent. In the case of a person's voice mixed with background noise the latter assumption usually is valid. The mixtures of the two sources could be different with respect to amplitude and/or phase of the two sources. In other words, by picking up sound signals with two differently oriented microphones the signal of each of these microphones will correspond to a mixture which is different with regard to the difference in amplitude and/or phase of the two acoustic sources (i.e. user's voice on the one hand and ambient noise on the other hand). By orienting one of the microphones outwardly towards the environment and the other microphone inwardly to the ear canal, a particularly large difference between the two mixtures can be obtained in a simple and particularly comfortable manner, i.e. no boom microphones or bone-conduction microphones which would cause discomfort to the user need to be used.

According to one embodiment, the two microphones are part of a hearing protection device. With such a configuration, the microphones can be arranged such that the ambient sound reaching the inwardly oriented microphone is attenuated by the hearing protection device relative to ambient sound reaching the outwardly oriented microphone. Although such hearing protection device could be an earmuff, according to a preferred embodiment the hearing protection device is an earplug comprising a shell which is to be inserted at least partially into the user's ear canal. According to one embodiment, the shell is a customized hard shell having an elasticity from shore D85 to D65 and having an outer shape according to the measured inner shape of the user's outer ear and ear canal. According to an alternative embodiment, the shell is a generic soft shell capable of adapting to the shape of the user's outer ear and ear canal.

Preferably, the inwardly oriented microphone is located at or is open to the inner part of the shell which is to be inserted into the ear canal, with the inwardly oriented microphone preferably being located at the inner end of the shell or within a channel of the shell open to the inner end of the shell.

Preferably, the outwardly oriented microphone is located at or is open to the outer part of the shell which is not to be inserted into the ear canal, with the outwardly oriented microphone preferably being located at the outer end of the shell or within a channel of the shell open to the outer end of the shell.

If the hearing protection device is an earmuff, the first microphone is located at or is open to the outer side of the earmuff and the second microphone is located at or is open to the inner side of the earmuff.

In all embodiments, the device preferably comprises a speaker adapted to provide an external audio signal to the user's ear. Thereby bidirectional communication with the user is achieved. Preferably the speaker is located at or is open to a portion of the device which is to be worn within the user's ear canal, whereby the speaker is brought acoustically close to the user's ear drum so that good intelligibility of the sound provided by the speaker is achieved even in noisy environments.

Usually the device will be binaural, i.e. it will comprise one unit for the right ear and another unit for the left ear. The speaker and the microphones may be integrated in the same unit, i.e. in at least one of the units, or the speaker may be part of the unit for one ear and the microphones may be part of the unit for the other ear.

According to one embodiment, the device may be adapted to be worn completely within the user's ear canal, whereby the device can be more or less completely hidden from the views of other persons. According to other embodiments, the device may be any other kind of a wired or wireless headset.

Preferably the audio signal processing unit is integrated within the device. In an alternative embodiment, the audio signal processing unit may be adapted to be worn behind the user's ear or somewhere at the user's body. In this case, although the device becomes more handy, more space, and hence also more power, is available for the audio signal processing unit, which may reduce the costs an/or may improve the performance of the blind source separation. In such case, the audio signal processing unit may be connected to the microphone either by wires, which is the most simple solution, or via a wireless link, for example, a radio frequency link such as Bluetooth link, an inductive link or an infrared link, which solution would result in enhanced wearing comfort for the user.

As a further alternative, the audio signal processing unit could be designed to be located remote from the user and is connected to the microphones via a radio frequency link such as Bluetooth link. In this case, there would be even less restrictions regarding the size and power consumption of the audio signal processing unit, which might result in reduced costs and/or increased performance of the blind source separation.

In all embodiments, the system preferably comprises a radio frequency transmitter for transmitting the processed audio signal output of the audio signal processing unit to a remote radio frequency receiver in order to provide the user's voice to another person. According to one embodiment, the radio frequency transmitter is integrated within the audio signal processing unit, i.e. the radio frequency transmitter may be either integrated within the device or it may be adapted to be worn behind the use's ear or at the user's body or it could be even located remote from the user. However, in an alternative embodiment, the radio frequency transmitter could be remote from the audio signal processing unit, in which case the processed audio signal output of the audio signal processing unit would be provided to a radio frequency transmitter by wires or via a radio frequency link, an inductive link or an infrared link. In this case the location of the audio signal processing unit and the radio frequency transmitter can be optimized independently form each other.

In all embodiments, the blind source separation algorithm preferably works in the frequency domain, i.e. the algorithm is simultaneously carried out in different frequency bands/bins and the outcomes of these bands/bins are combined in an appropriate way.

In all embodiments, the blind source separation algorithm preferably works with the assumption that the sources are statistically independent, i.e. that the user's voice is independent of the ambient sound.

These and further objects, features and advantages of the present invention will become apparent from the following description when taken in connection with the accompanying drawings which, for purposes of illustration only, show several embodiments in accordance with the present invention.

### BRIEF DESCRIPTION OF THE DRAWINGS

FIG. 1 is a schematic view of a first embodiment of a hearing protection earplug system according to the invention inserted into a person's ear canal with a block diagram of the most relevant electronic components;

FIG. 2 is a schematic view of a modified embodiment of a hearing protection earplug according to the invention;

FIGS. 3 and 4 show further modified embodiments of a system according to the invention;

FIG. 5 shows a modification of the embodiment of FIG. 1; and

FIG. 6 shows a modification of the embodiment of FIG. 5.

### DETAILED DESCRIPTION OF THE INVENTION

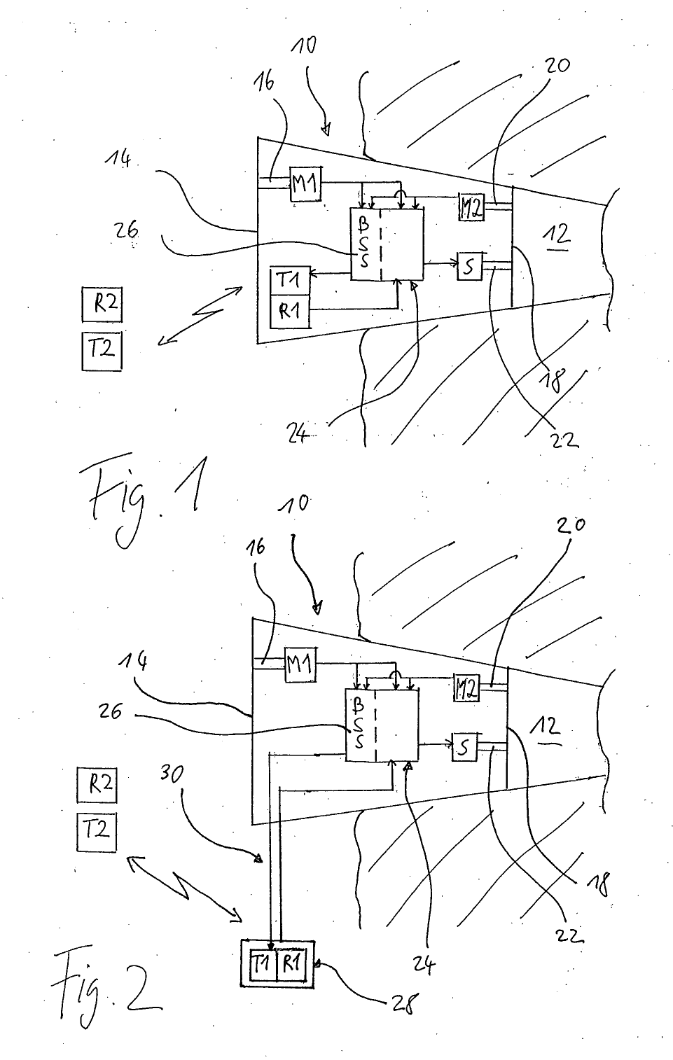

The system of FIG. 1 comprises a hearing protection earplug 10 which may have a hard shell with an elasticity from shore D85 to shore D65, which is customized, i.e. it has an outer shape according to the individual measured inner shape of the user's outer ear and ear canal. The hard shell may be manufactured by layer-by-layer laser sintering of a powder material, for example, polyamide powder, or by laser stereo-lithography or photo-polymerization. An overview regarding such additive layer-by-layer build-up processes for manufacturing customized shells of hearing devices can be found, for example, in US 2003/0133583 A1 or U.S. Pat. No. 6,533,062 B1. The inner shape of the person's ear canal and outer ear can be measured, for example, by taking an impression which then undergoes laser scanning or by direct laser scanning of the ear.

Preferably the hard shell is designed such that it provides for an acoustic attenuation, averaged over the audible frequency range, of at least 10 dB when inserted into the user's ear canal.

Rather than having a customized hard shell, earplug 10 may have a generic soft shell which adapts to the shape of the users outer ear and ear canal due to its elasticity.

In FIG. 1 the earplug 10 is shown to be inserted with its inner end portion into a user's ear canal 12. The earplug 10 comprises an outer microphone M1, which is located at the outer part of the earplug 10 and which is open to the outer end 14 of the earplug 10 via a sound channel 16, and an inner microphone M2, which is located at the inner part of the earplug 10 and which is open to the inner end 18 of the earplug 10 via a sound channel 20. The earplug 10 further comprises a speaker S which is likewise located at the inner part of the earplug 10 and is open to the inner end 18 via a sound channel 22. The earplug 10 also includes a digital audio signal processing unit 24 comprising a digital signal processor as well as a radio frequency transmitter unit T1 and a radio frequency receiver unit R1. The audio signal processing unit 24 functionally includes a unit 26 for applying a blind source separation algorithm to the audio signals provided by the microphones M1 and M2. It is evident to the skilled person that the earplug 10 includes additional electrical components, such as amplifiers and analogue-to-digital converters for the audio signals provided by the microphones M1 and M2, a digital-to-analogue converter and an amplifier for the audio signal to be transformed into sound by the speaker S, program and data memory components for the audio signal processing unit 24, a battery for power supply, a demodulator, a modulator, an antenna, etc., which are not shown in FIG. 1 for the sake of simplicity.

The transmitter T1 of the earplug 10 is adapted to transmit audio signals from the earplug 10 to a remote receiver R2 via a radio link, while the receiver R1 of the earplug 10 is adapted to receive audio signals from a remote transmitter T2. The audio signals received by the receiver R1 are demodulated and then undergo signal processing in the audio signal processing unit 24 as input to the speaker S in order to provide remote audio signals to the user. Such remote audio signals could be the speech of another person picked up by a microphone whose output is sent to the remote transmitter T2 by wires or via, for example, a mobile telephone or mobile radio device.

The audio signals provided by the microphones M1 and M2 are passed as input to the blind source separation unit 26, in which a processed audio signal output for the transmitter T1 is produced, with the processed audio signal output consisting completely or at least essentially of the user's voice which has been separated from the ambient sound by action of the blind source separation algorithm carried out in the BSS unit 26. Such BSS signal processing utilizes the fact that the sound mixtures picked up by the microphone M1 which is oriented towards the environment and M2 which is oriented towards the ear canal 12, respectively, consist—due to the different orientation of the microphones M1 and M2—of essentially different mixtures of the ambient sound and the user's voice, which are different regarding amplitude ratio of these two signal contributions or sources (i.e. ambient sound on the one hand and user's voice on the other hand) and regarding phase difference of these two signal contributions of the mixture.

The output signal of the BSS unit 26 is transmitted via the transmitter T1 to the remote receiver R2 which usually will be connected to a remote speaker for presenting the user's voice to another person. The remote speaker and the remote microphone connected to the remote transmitter T2 could be part of an earpiece or an earplug worn by another person, which may be similar or identical to the earplug 10. Thereby in-the-ear hearing protection devices with integrated communication function can be achieved. Such a system could be used by any persons who need to communicate in a noisy environment, such as workers, soldiers, firemen, etc. However, the remote receiver R2 also might serve for communication via a mobile telephone or a mobile radio device.

In general, the remote receiver R2/transmitter T2 could be a part of an interface of a standard wireless communication device, such as a mobile telephone device or a mobile radio device Preferably, the wireless link between the transmitter T1/receiver R1 and the remote receiver R2/remote transmitter T2 is a Bluetooth link. The remote receiver R2/transmitter T2 then could be a part of the Bluetooth interface of a standard wireless communication device, such as a mobile telephone device or a mobile radio device.

According to FIG. 1, the audio signal produced by the microphones M1 and M2, which is used as input to the BSS unit 26, in addition could undergo other audio signal processing within the audio signal processing unit 24, for example, in order to provide the ambient sound picked up by the microphone M1 to the speaker S for enabling perception of desired ambient sounds during times when the noise level is low so that the hearing protection function provided by the earplug 10 is not needed, or to provide for an in-situ measurement of the actual acoustic attenuation provided by the earplug 10 when inserted into the user's ear canal 12 by comparing the sound levels measured by the microphones M1 and M2.

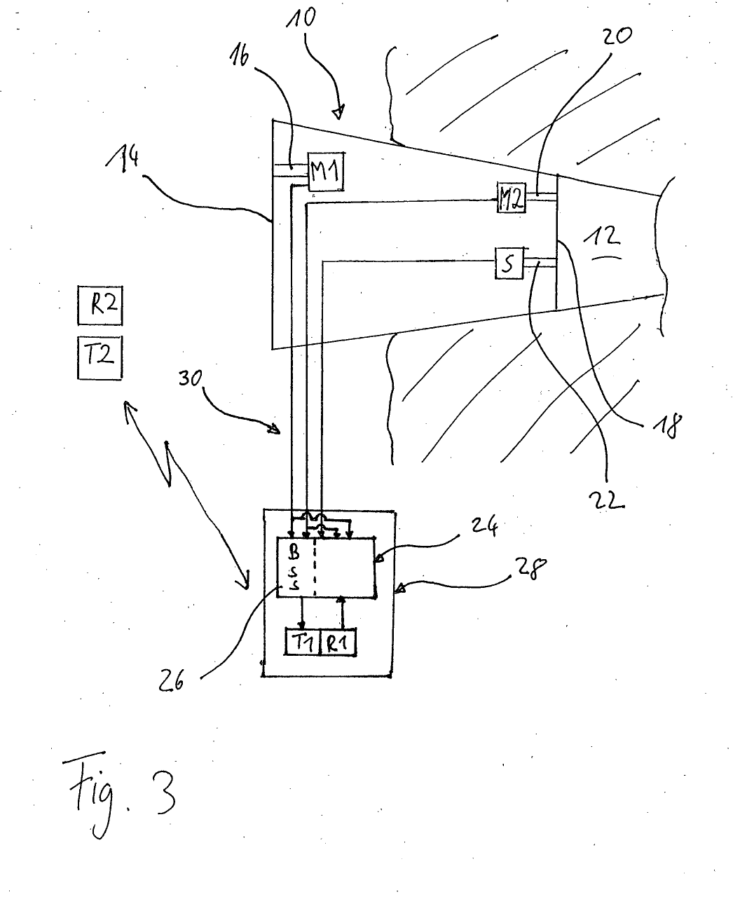

In FIG. 2 a modified embodiment is shown, wherein the transmitter T1 and the receiver R1 have been removed from the earplug 10 and now are located in an external unit 28 which is connected by wires 30 to the earplug 10 and which is to be worn at an appropriate location at the user's body, for example behind the user's ear or somewhere within or below the user's clothing, for example, within a helmet. The external unit 28 may include further electrical components removed from the earplug 10, for example, the power supply battery.

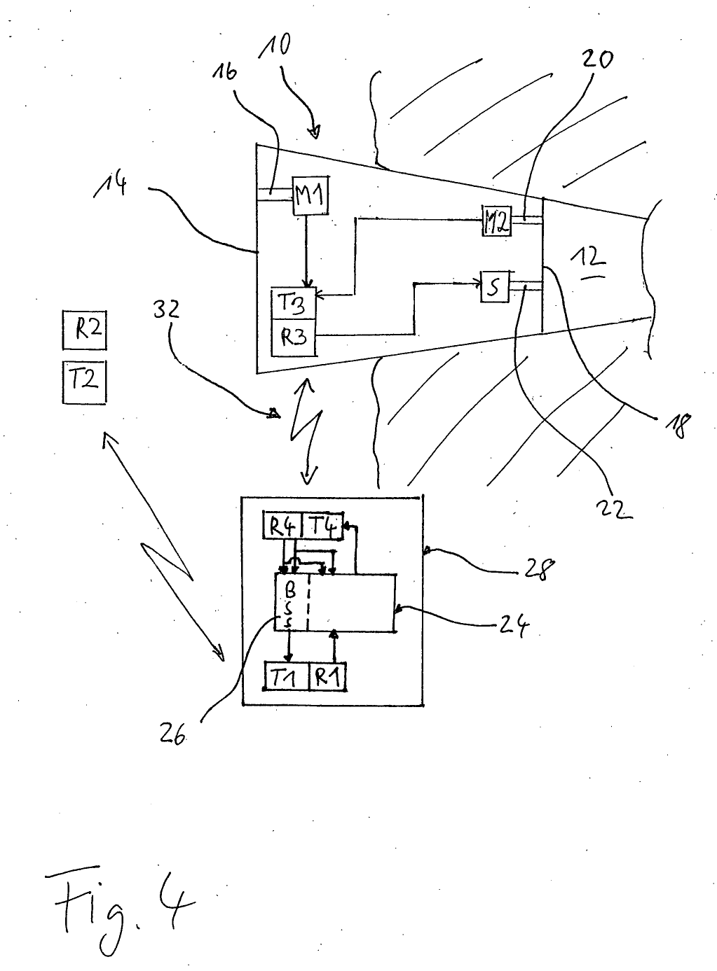

In FIG. 3 a further modified embodiment is shown, wherein not only the transmitter T1 and the receiver R1 (and the power supply battery) but in addition also the audio signal processing unit 24 including the BSS unit 26 has been removed from the earplug 10 and is connected via corresponding wires to the microphones M1 and M2 and the speaker S, respectively.

In FIG. 4 a still further modified embodiment is shown, wherein the wire connection 30 between the earplug 10 and the external unit 28 has been replaced by a bidirectional wireless link 32, which is established by a transmitter T3 and a receiver R3 located in the earplug 10 and a corresponding receiver R4 and transmitter T4 located in the external unit 28. The wireless link 32 could be a radio frequency link, an inductive link or an infrared link. If it is an inductive link, the external unit 28 would have to be located relatively close to the earplug 10, for example at a distance of not more than 20 cm. With an RF link, the distance could be larger; in this case it would be even be possible to locate the external unit 28 at a position remote from the user's body, for example, within a distance of a few meters. Preferably the wireless link 32 of the embodiment of FIG. 4 is a Bluetooth link.

Although in the embodiments shown is FIGS. 1 to 4 the speaker S is shown as being integrated in the same earplug 10 as the microphones M1 and M2, in other embodiments the speaker S may be provided at an earplug other than the earplug at which the microphones M1 and M2 are provided.

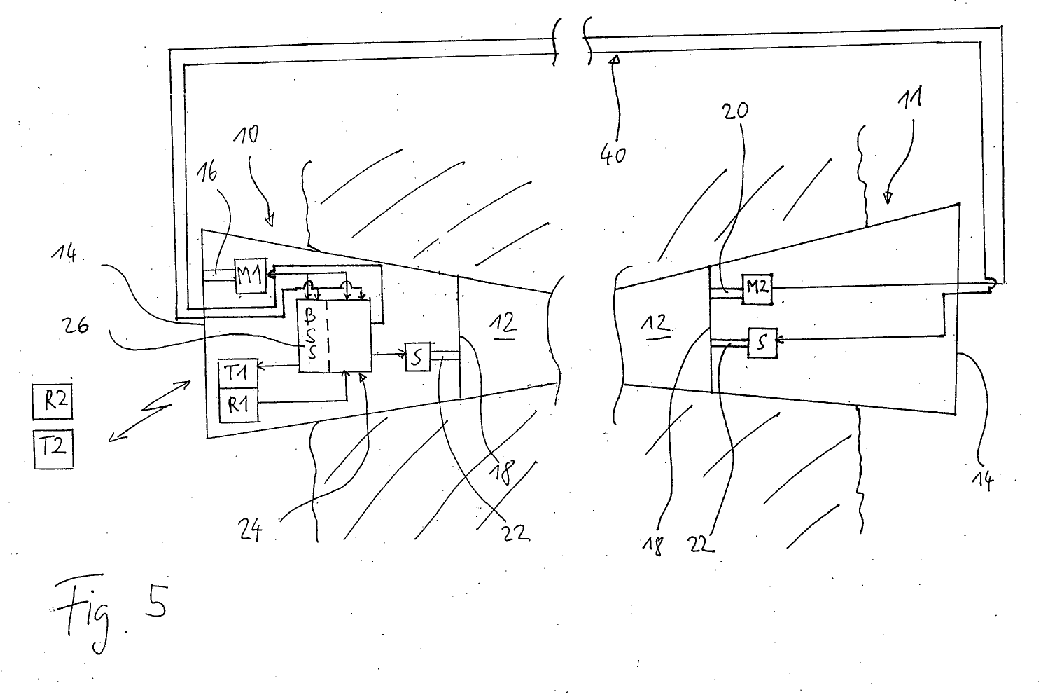

FIG. 5 shows a modified version of the embodiment of FIG. 1, wherein the inwardly oriented second microphone M2 is not part of the earplug 10—as shown in FIG. 1—but rather is provided at the earplug 11 for the other ear. The second microphone M2 is located at the inner part of the earplug 11 and is open to the inner end 18 of the earplug 11 via a sound channel 20. In addition, the earplug 11 further comprises a speaker S which is likewise located at the inner part of the earplug 11 and is open to the inner end 18 via a sound channel 22. The microphone M2 and the speaker S of the earplug 11 are connected to the audio signal processing unit 24 located in the earplug 10 via a wire connection 40 which be integrated in a mechanical connection (not shown) between the earplugs 10 and 11 which may be provided for preventing loss of the earplugs 10, 11.

According to a modification of the embodiment of FIG. 5, the outwardly oriented first microphone M1 may be provided at the earplug 11, while the inwardly oriented second microphone M2 may be provided at the earplug 10 as in FIG. 1.

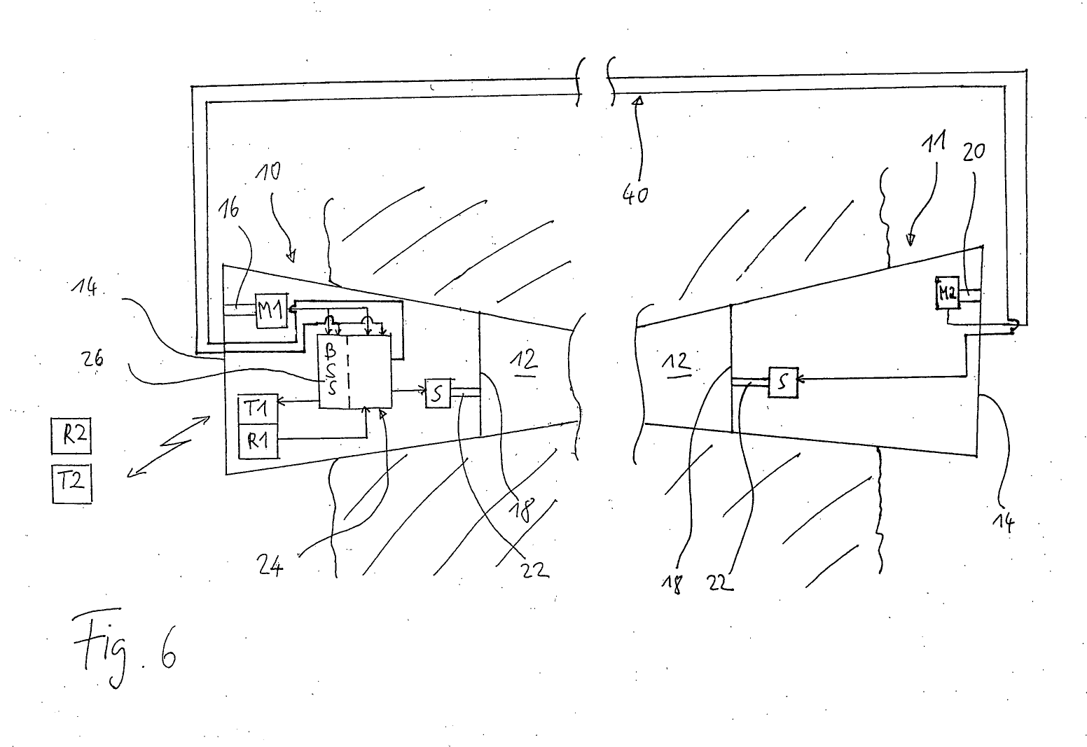

An alternative modification of the embodiment of FIG. 5 is shown in FIG. 6, wherein both the first microphone M1 of the earplug 10 and the second microphone M2 of the earplug 11 are outwardly oriented. In this case the differences in the sound mixtures picked up by the microphone M1 of the earplug 10 and the microphone M2 of the earplug 11 are due to the different location of the microphone M1 at one ear and the microphone M2 at the other ear (for example, a disturbing noise source usually will be located closer to one of the two ears and hence will contribute more strongly and with different phase to the signal picked up by the microphone located at that ear than to that located at the other ear).

According to a modification of the embodiment of FIG. 6 both microphones M1 and M2 could be inwardly oriented rather than outwardly oriented.

While FIGS. 5 and 6 and the above-discussed variants thereof are modifications of the embodiment of FIG. 1, according to which both the audio signal processing unit 24 and the transmitter T1/receiver R1 are part of the earplug 10, it is to be understood that the embodiments of FIGS. 2 to 4 may be analogously modified, i.e. by providing the second microphone M2 at the earplug 11 rather than at the earplug 10.

While the examples discussed so far relate to an application of the communication system to hearing protection earplugs, the invention also may be applied to earmuffs serving as a hearing protection device or generally to any kind of headset, i.e. also to hearing devices which do not provide for a hearing protection function. For example, the headset may consist of a device with a customized or a generic shell which is designed such that it can be worn completely in the ear canal 12 (i.e. as a “CIC device”) and which serves exclusively communication purposes, for example, for security persons, policemen, firemen, etc., i.e. for persons who are exposed to a noisy environment, with the noise level, however, being below a threshold value which would require the use of hearing protection devices. Such CIC device generally could have the construction of the earplug of FIG. 1, however, without considerable acoustic attenuation provided due to the material and the design of the shell, and would be reduced in size so that it can be worn completely within the ear canal 12.

In general, the device need not be designed as an earplug but it may rather be any kind of headset.

While various embodiments in accordance with the present invention have been shown and described, it is understood that the invention is not limited thereto, and is susceptible to numerous changes and modifications as known to those skilled in the art. Therefore, this invention is not limited to the details shown and described herein, and includes all such changes and modifications as encompassed by the scope of the appended claims.

What is claimed is:

1. A system for separation of a user's voice from ambient sound, comprising a device to be worn at a user's ear or at least partly in a user's ear canal and comprising a first microphone oriented outwardly towards an environment and a second microphone oriented inwardly towards said user's ear canal, and an audio signal processing unit for processing audio signals from said first and second microphone by a blind source separation algorithm adapted to separate a user's voice from ambient sound.

2. The system of claim 1, wherein said device is designed as a hearing protection device.

3. The system of claim 2, wherein said hearing protection device is designed to provide for an acoustic attenuation, averaged over an audible frequency range, of at least 10 dB.

4. The system of claim 3, wherein said microphones are arranged such that ambient sound reaching said second microphone is attenuated by said hearing protection device relative to ambient sound reaching said first microphone.

5. The system of claim 2, wherein said hearing protection device is an earplug comprising a shell which is to be inserted at least partially into said user's ear canal.

6. The system of claim 5, wherein said shell is a hard shell having an elasticity from Shore D 85 to Shore D 65 and having an outer shape according to a measured inner shape of said user's outer ear and ear canal.

7. The system of claim 5, wherein said second microphone is located at or is open to an inner part of said shell, which inner part is to be inserted into said ear canal.

8. The system of claim 7, wherein said second microphone is located at an inner end of said shell or within a channel of said shell open to an inner end of said shell.

9. The system of claim 5, wherein said first microphone is located at or is open to an outer part of said shell, which outer part is not to be inserted into said ear canal.

10. The system of claim 9, wherein said second microphone is located at an outer end of said shell or within a channel of said shell open to an outer end of said shell.

11. The system of claim 1, wherein said hearing protection device is an earmuff and wherein said first microphone is located at or is open to an outer side of said earmuff and said second microphone is located at or is open to an inner side of said earmuff.

12. The system of claim 1, wherein said device comprises a speaker adapted to provide an external audio signal to said user's ear.

13. The system of claim 12, wherein said speaker is located at or within a channel open to that end of said device which is to be worn within said user's ear canal.

14. The system of claim 1, wherein said device is adapted to be worn completely within said user's ear canal.

15. The system of claim 1, wherein said audio signal processing unit is integrated within said device.

16. The system of claim 1, wherein said audio signal processing unit is adapted to be worn behind said user's ear or at a user's body.

17. The system of claim 16, wherein said audio signal processing unit is connected to said microphones by wires or via a radio frequency link, an inductive link or an infrared link.

18. The system of claim 1, wherein said audio signal processing unit is designed to be located remote from said user and is connected to said microphones via a radio frequency link.

19. The system of claim 1, wherein said system comprises a radio frequency transmitter (for transmitting a processed audio signal output of said audio signal processing unit to a remote radio frequency receiver in order to provide a user's voice to another person.

20. The system of claim 19, wherein said remote radio frequency receiver is part of a Bluetooth interface of a mobile telephone or a mobile radio system.

21. The system of claim 19, wherein said radio frequency transmitter is integrated with said audio signal processing unit.

22. The system of claim 19, wherein said radio frequency transmitter is remote from said audio signal processing unit and wherein a processed audio signal output of said audio signal processing unit is provided to said radio frequency transmitter by wires or via an inductive link.

23. The system of claim 12, wherein the system comprises a radio frequency receiver for receiving said external audio signal from a remote radio frequency transmitter.

24. The system of claim 23, wherein said remote radio frequency transmitter is part of a Bluetooth interface of a mobile telephone or a mobile radio system.

25. A system for separation of a user's voice from ambient sound, comprising: a first device to be worn at a user's right ear or at least partly in a user's right ear canal, a second device to be worn at a user's left ear or at least partly in a user's left ear canal, said first device comprising a first microphone and said second device comprising a second microphone, and an audio signal processing unit for processing audio signals from said first and second microphone by a blind source separation algorithm adapted to separate a user's voice from ambient sound.

26. The system of claim 25, wherein one of said first microphone and second microphone is oriented outwardly towards an environment and the other one of said first microphone and second microphone is oriented inwardly towards said user's ear canal.

27. The system of claim 25, wherein said audio signal processing unit is located in one of said first device and said second device or is adapted to be worn behind a user's ear or at a user's body or is designed to be located remote from said user and is connected to said microphones via a radio frequency link.

28. A method for separation of a user's voice from ambient sound, comprising:
providing the user with a device to be worn at a user's ear or at least partly in a user's ear canal and comprising a first microphone oriented towards an environment and a second microphone oriented towards said user's ear canal,
picking up sound by said first microphone to create a first audio signal and by said second microphone to create a second audio signal, and
processing said first and second audio signals by a blind source separation algorithm in order to produce a processed audio signal wherein said user's voice is separated from ambient sound.

29. A method for separation of a user's voice from ambient sound, comprising:
providing said user with a first device to be worn at a user's right ear or at least partly in a user's right ear canal and a second device to be worn at a user's left ear or at least partly in a user's left ear canal, said first device comprising a first microphone and the second device comprising a second microphone,
picking up sound by said first microphone to create a first audio signal and by said second microphone to create a second audio signal, and
processing said first and second audio signals by a blind source separation algorithm in order to produce a processed audio signal wherein said user's voice is separated from ambient sound.

30. The method of claim 28, wherein said blind source separation algorithm works in the frequency domain.

31. The method of claim 28, wherein said processed audio signal is provided to another person via a wireless link.
